(19) United States
(12) Patent Application Publication
(10) Pub. No.: US 2026/0090204 A1
(43) Pub. Date: Mar. 26, 2026

(54) DISPLAY DEVICE

(71) Applicant: CANON KABUSHIKI KAISHA, Tokyo (JP)

(72) Inventor: AKIHITO KOMAZAWA, Kanagawa (JP)

(21) Appl. No.: 19/327,208

(22) Filed: Sep. 12, 2025

(30) Foreign Application Priority Data
Sep. 20, 2024 (JP) 2024-164109
Apr. 21, 2025 (JP) 2025-069279

(51) Int. Cl. H10K 59/121; H10K 59/60

(52) U.S. Cl. CPC H10K 59/121; H10K 59/60

(57) ABSTRACT

A display device includes a display area provided on a substrate and including a visible-light-emitting element, and a first infrared light-emitting area provided on the substrate and including an infrared light-emitting element. In a plan view of the substrate, the first infrared light-emitting area circumscribes the display area and is positioned between the display area and a polygon containing the display area.

### BACKGROUND

### Field of the Technology

The present disclosure relates to a display device having an infrared light-emitting area.

### Description of the Related Art

Recent display devices are used in various applications, and are used in various types of mobile devices. A display device installed on a wearable device as a display is configured to detect the line of sight of a user, and to make a display on the basis of such line-of-sight information.

As a method for detecting the line of sight in such a display device, a method using infrared light has been known. As such a display device, a display device having an infrared light-emitting element configured to emit infrared light, as well as a light-emitting element configured to emit visible light for displaying an image, has been known.

Japanese Patent Laid-Open No. 2021-15731 discloses a display device having a display element and an infrared light-emitting element on the same substrate.

In Japanese Patent Laid-Open No. 2021-15731, a display area and an infrared light-emitting area are disposed spaced apart from each other. Therefore, it is necessary to increase the incident angle of the infrared light with respect to the line connecting the center of the display area and an user's eyeball, and, depending on the direction of the user's line of sight, this increase in the incident angle may result in a failure in the line-of-sight detection based on Purkinje images, which is a detection that uses the light reflected from the cornea, and may lead to a deterioration in the detection accuracy.

### SUMMARY

The present disclosure has been made with the foregoing in view, and provides a technique for improving the detection accuracy of the line of sight of a user in a display device having a display area and an infrared light-emitting area.

According to some embodiments, a display device includes a display area provided on a substrate and including a visible-light-emitting element, and a first infrared light-emitting area provided on the substrate and including an infrared light-emitting element, wherein in a plan view of the substrate, the first infrared light-emitting area circumscribes the display area and is positioned between the display area and a polygon containing the display area.

Features of the present disclosure will become apparent from the following description of embodiments with reference to the attached drawings. The following description of embodiments is described by way of example.

### BRIEF DESCRIPTION OF THE DRAWINGS

FIG. 1 is a system diagram illustrating a schematic configuration of a display device according to a first embodiment.

FIG. 2 is a schematic plan view of the display device according to the first embodiment.

FIG. 3 is a schematic plan view of a display device according to a second embodiment.

FIG. 4 is a schematic plan view of a display device according to a third embodiment.

FIG. 5 is a schematic plan view of a display device according to a fourth embodiment.

FIGS. 6A and 6B are diagrams each illustrating an example of pixels that are elements of a display device according to one embodiment.

FIG. 7 is a view illustrating one example of a configuration of a display device according to one embodiment.

FIGS. 8A and 8B are diagrams each illustrating an application example of a display device according to one embodiment.

FIGS. 9A and 9B are diagrams each illustrating one example of an HMD as a display device according to one embodiment.

### DESCRIPTION OF THE EMBODIMENTS

Embodiments will now be explained with reference to the accompanying drawings. The following embodiments are not intended to limit the scope of claims. While a plurality of features are described in the following embodiments, not all of the plurality of features are essential to the present disclosure, and the plurality of features may be combined in any way. Furthermore, a display device may be configured by combining the embodiments as appropriate. Moreover, the same or similar components will be given the same reference numeral in the accompanying drawings, and redundant descriptions will be omitted.

### First Embodiment

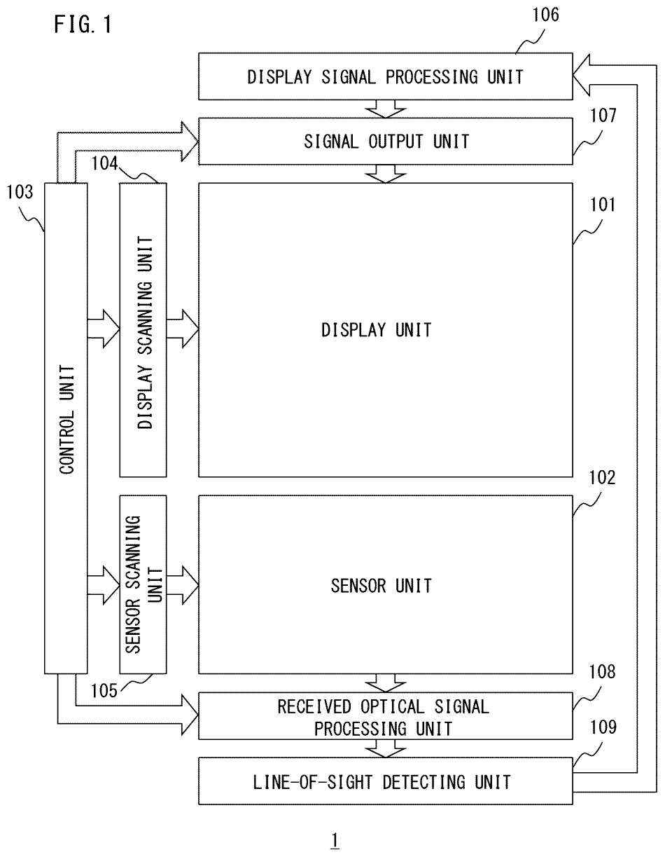

A display device according to a first embodiment will now be explained. FIG. 1 is a system diagram illustrating a schematic configuration of a display device 1 according to this embodiment. As illustrated in FIG. 1, the display device 1 includes a display unit 101, a sensor unit 102, a control unit 103, a display scanning unit 104, a sensor scanning unit 105, a display signal processing unit 106, a signal output unit 107, a received optical signal processing unit 108, and a line-of-sight detecting unit 109.

The display unit 101 includes a visible-light-emitting element, an infrared light-emitting element, and driving circuits for the respective light-emitting elements. The signal output unit 107 is controlled by the control unit 103, and outputs a brightness signal to the display unit 101. The display scanning unit 104 is controlled by the control unit 103, and writes the brightness signal received from the signal output unit 107 to a predetermined pixel in the corresponding column in the display device 1. The sensor unit 102 has a light-receiving element, such as a photodiode, having sensitivity in the infrared range. Infrared light emitted from the infrared light-emitting element of the display unit 101 reflects on the user's eyeball of the display device 1, and the reflected light from the eyeball is received by the sensor unit 102. The sensor scanning unit 105 selects a predetermined pixel in the corresponding column of the display device 1, and the signal generated at the pixel is output to the received optical signal processing unit 108. The received optical signal processing unit 108 includes elements such as a correlated double sampling (CDS) circuit for noise reduction and an analogue-to-digital converter (ADC). The line-of-sight detecting unit 109 identifies the vector of the user's line of sight with respect to the display unit 101, by performing a computation on a signal processed by the received optical signal processing unit 108.

In the display device 1 according to this embodiment, as a method for detecting the user's line of sight with respect to the display unit 101 from a captured image of an eye, the captured image being captured using infrared light, a line-of-sight detection based on a Purkinje image, which is formed by the reflection of illuminating light on the cornea of the user's eye, is used. Specifically, the display device 1 detects the user's line of sight using what is called a pupil-corneal reflection method that calculates a line-of-sight vector representing the direction in which the eyeball is directed on the basis of the image of the pupil and the Purkinje image included in the captured image of the user's eyeball.

The display signal processing unit 106 performs data processing for displaying images corresponding to the position of the user's line of sight, by using the line-of-sight vector information obtained by the line-of-sight detecting unit 109. Specifically, the display unit 101 is divided into two areas in advance, that is, divided into an area to be gazed by the user and a surrounding area, and the display signal processing unit 106 performs data processing for setting a lower resolution to the surrounding area than that set to the area to be gazed by the user. By setting a lower resolution to the surrounding area than that set to the area to be gazed in the display unit 101, the amount of display data can be reduced, so that the power consumption and the displaying delay on the display device 1 can be reduced. The data processing using such a method is called foveated rendering (FR).

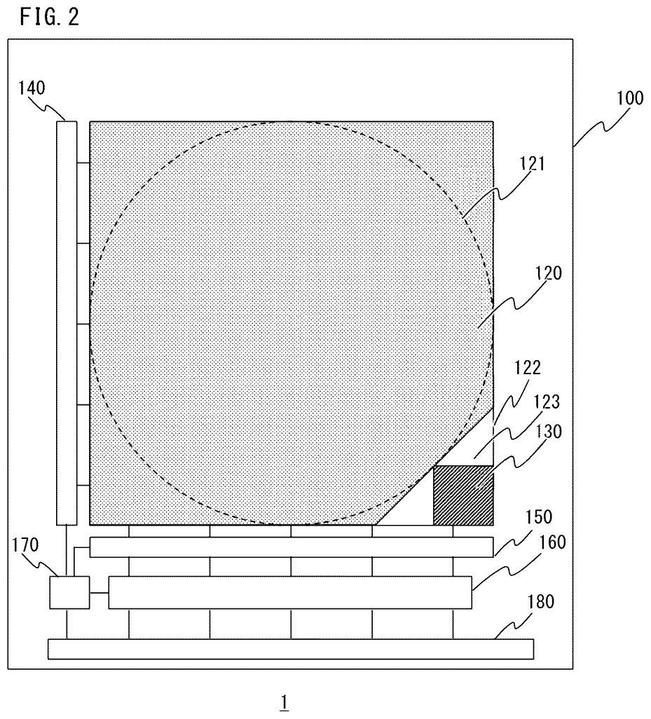

FIG. 2 is a schematic plan view of the display device 1 according to this embodiment. In the display device 1 according to the embodiment, a display area 120, an infrared light-emitting area 130, a display scanning circuit 140, a demultiplexer 150, a source driver 160, a control circuit 170, and a pad 180 are disposed on a substrate 100.

The display area 120 has a visible-light-emitting element, such as an organic EL element, capable of emitting visible light. In a plan view of the substrate 100, the display area 120 is a polygonal (pentagonal, in FIG. 2) area. The plan view of the substrate 100 herein means a view of the substrate 100 along the normal direction of the substrate 100. In a display device used for line-of-sight detection, the user basically gazes at an area near the center, and when an ocular optical system has a circular shape (the circle 121 indicated with the broken line in FIG. 2), the corners of the display area 120 around the circle 121, the corners being on the periphery, are often outside of the field of view. Therefore, in this embodiment, the infrared light-emitting area 130 circumscribes the display area 120 and is disposed at a corner of a quadrangle 122, which is an example of a polygon containing the display area 120, in a plan view of the substrate 100. In this manner, in this embodiment, the infrared light-emitting area 130 is disposed between the contour of the quadrangle 122 and the display area 120, that is, in an area 123 where the quadrangle 122 does not overlap with the display area 120.

The infrared light from the infrared light-emitting area 130 needs to be emitted toward an eyeball of the user gazing at the center of the display area 120 (the center of the circle 121), and the infrared light is emitted at a predetermined incident angle with respect to a line connecting the center of the display area 120 and the eyeball of the user. The infrared light-emitting area 130 herein corresponds to a first infrared light-emitting area including an infrared light-emitting element. In the conventional display device, depending on the direction of the user's line of sight, the method of the detecting line of sight on the basis of a Purkinje image, which uses the light reflected from the cornea, may be infeasible, and the detection accuracy may deteriorate. By contrast, with the display device 1 according to this embodiment, by disposing the infrared light-emitting area 130 at a corner of the quadrangle 122, the infrared light-emitting area 130 can be positioned nearer to the center of the display area 120, than that in the conventional display device. With this, the infrared light becomes incident on the user's eyeball at a smaller incident angle, so that the probability of detecting corneal reflection is improved. Therefore, it is possible to achieve a display device with highly accurate line-of-sight detection. Furthermore, because the display area 120 and the infrared light-emitting area 130 are positioned on the same substrate 100, it is possible to reduce the size of the display device 1. This size reduction also leads to a reduction in the size of the line-of-sight detection system using the display device 1. Note that it is also possible to dispose an element such as what is called a dummy pixel or a driving circuit for the infrared light-emitting element, between the display area 120 and the infrared light-emitting area 130.

The display scanning circuit 140 drives the display area 120 when a brightness signal is to be written to a pixel in the display area 120, by supplying a write control signal to a scan line. The source driver 160 drives a signal line corresponding to a pixel via the demultiplexer 150, to bring the voltage of the signal line to an intended signal voltage. When the source driver 160 drives the signal line corresponding to the pixel, the demultiplexer 150 selects, by switching switches, the signal line of the corresponding color, in the corresponding column. The control circuit 170 sends control signals to the display scanning circuit 140, the demultiplexer 150, and the source driver 160. The pad 180 is connected to the control circuit 170 and the source driver 160, and receives external clock signals, image data, and the like. It is assumed herein that the sensor unit, the display signal processing circuit, the line-of-sight detection circuit, and the like are present outside the substrate 100, but these components may be disposed on the substrate 100. This arrangement will be specifically described later.

### Second Embodiment

A display device according to a second embodiment will now be explained. In the following description, configurations that are the same as those in the first embodiment will be given the same reference numerals, and detailed descriptions thereof will be omitted.

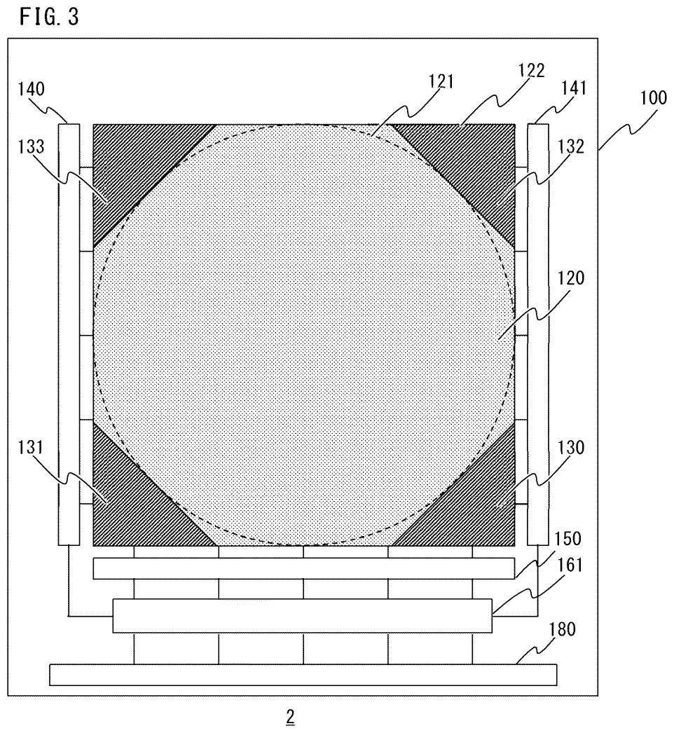

FIG. 3 is a schematic plan view of a display device 2 according to the second embodiment. In the display device 2 according to this embodiment, the display area 120, infrared light-emitting areas 130 to 133, display scanning circuits 140, 141, and the demultiplexer 150 are disposed on the substrate 100. In the display device 2, a display driver integrated circuit (DDIC) 161 and the pad 180 are also disposed on the substrate 100.

In a plan view of the substrate 100, the display area 120 has a polygonal shape with four corners of a quadrangle removed (an octagonal shape in FIG. 3). Infrared light-emitting areas 130, 131, 132, 133 circumscribe the display area 120 and are disposed at the four respective corners of the quadrangle 122, which is an example of a polygon containing the display area 120. One of the infrared light-emitting areas 130 to 133 corresponds to a first infrared light-emitting area, and another one of the infrared light-emitting areas 130 to 133 other than the first infrared light-emitting area corresponds to a second infrared light-emitting area. By positioning the infrared light-emitting areas at the respective corners of the quadrangle 122, infrared light can be emitted toward the eyeball of the user from four directions. With this, even if the user's line of sight is off the center of the display area 120, the probability at which the light reflected from the cornea of the user's eyeball is detected is increased, and the accuracy of the line-of-sight detection is improved. Furthermore, each of the infrared light-emitting areas 130 to 133 may have a triangular shape, as illustrated in FIG. 3. By making the shape of each of the infrared light-emitting areas 130 to 133 triangular, the areas of the infrared light-emitting areas 130 to 133 are increased, and the amount of infrared light can be increased, as compared with the configuration according to the first embodiment (FIG. 2). Each of the infrared light-emitting areas 130 to 133 may also have a quadrangular shape, in the same manner as in the first embodiment (FIG. 2), or any other shape. The circle 121 representing the ocular optical system may be inscribed in the polygon delineated by the display area 120, in a plan view.

Furthermore, not all of the four corners of the quadrangle 122 may be provided with the infrared light-emitting areas. For example, the infrared light-emitting areas may be disposed at different positions of facing corners of the quadrangle 122, with the display area 120 therebetween. In other words, it is also possible to use a configuration provided with the infrared light-emitting areas 130, 133 but not provided with at least one of the infrared light-emitting areas 131, 132, or a configuration provided with the infrared light-emitting areas 131, 132 but not provided with at least one of the infrared light-emitting areas 130, 133, in FIG. 3. With such configurations, too, the reflection of the infrared light from the cornea of the user's eyeball is detected at a higher probability, as compared with that in the first embodiment (FIG. 2).

The display scanning circuits 140, 141 supply a write control signal to a scanning line when a brightness signal is to be written to a pixel in the display area 120. As illustrated in FIG. 3, by positioning the display scanning circuits 140, 141 on two respective sides of the display area 120, it is possible to increase the driving power for the scanning lines. The DDIC 161 is a driving chip including a source driver, a control circuit, and a display signal processing circuit. Assumed herein is an example of a chip-on-chip (CoC) configuration in which the DDIC 161 is directly mounted on the substrate 100, but a chip-on-film (CoF) configuration, in which the DDIC 161 is mounted on a flexible substrate connected to the pad 180, may also be used.

### Third Embodiment

A display device according to a third embodiment will now be explained. In the following description, configurations that are the same as those in the first and the second embodiments will be given the same reference numerals, and detailed descriptions thereof will be omitted.

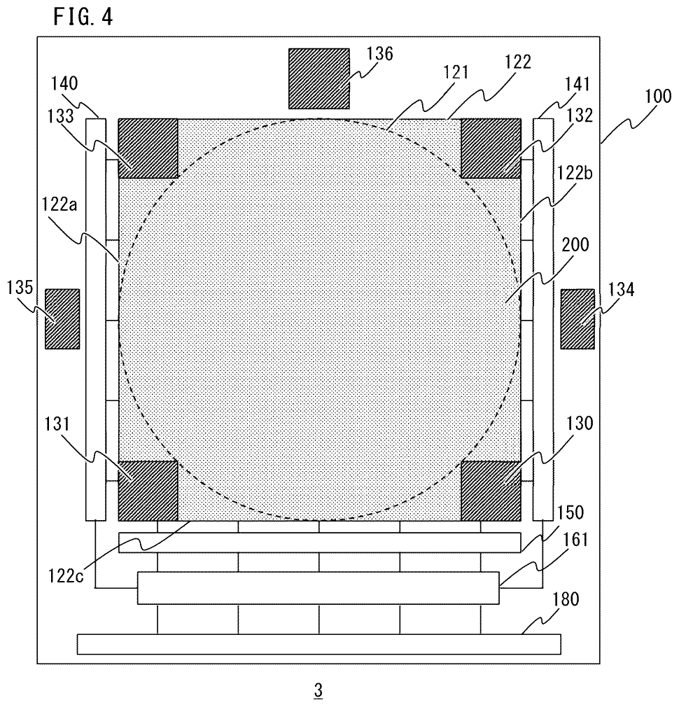

FIG. 4 is a schematic plan view of a display device 3 according to the third embodiment. In the display device 3 according to this embodiment, the display area 120, infrared light-emitting areas 130 to 136, the display scanning circuits 140, 141, the demultiplexer 150, the DDIC 161, and the pad 180 are disposed on the substrate 100.

In a plan view of the substrate 100, the display area 120 has a polygonal shape with the four corners of a quadrangle removed (dodecagonal shape in FIG. 4). The infrared light-emitting areas 130 to 133 circumscribe the display area 120 and are disposed at the four respective corners of the quadrangle 122, which is an example of a polygon containing the display area 120. The display scanning circuit 140 is disposed outside of the quadrangle 122, along one side (first side) 122a of the quadrangle 122. Similarly, the display scanning circuit 141 is disposed along another side (first side) 122b of the quadrangle 122. The DDIC 161 for the display area 120 is disposed outside of the quadrangle 122, along one side (second side) 122c of the four sides of the quadrangle 122, the side 122c being a side different from the sides facing the display scanning circuits 140, 141. Furthermore, the infrared light-emitting areas 134 to 136 are disposed on the outer side of the quadrangle 122 and the display scanning circuits 140, 141. Each of these infrared light-emitting areas 134 to 136 herein corresponds to a third infrared light-emitting area disposed outside of the quadrangle 122 and including an infrared light-emitting element.

The infrared light-emitting areas 134 to 136 may be driven by receiving control signals from the display scanning circuits 140, 141 and the DDIC 161, or may be connected to the pad 180 and driven by receiving control signals from outside of the substrate 100. In this embodiment, because the number of infrared light-emitting areas are greater, compared with those in the first and second embodiments, the probability at which the reflection of the infrared light from the cornea is detected can be further increased, and the accuracy of the line-of-sight detection is improved. In FIG. 4, three infrared light-emitting areas 134 to 136 are disposed outside the quadrangle 122 and the display scanning circuits 140, 141, as an example. However, the number of infrared light-emitting areas disposed outside the quadrangle 122 and the display scanning circuits 140, 141 is not limited thereto. By disposing at least one or more infrared light-emitting areas outside the quadrangle 122 and the display scanning circuits 140, 141, it is possible to improve the detection accuracy.

### Fourth Embodiment

A display device according to a fourth embodiment will now be explained. In the following description, configurations that are the same as those in the first to the third embodiments will be given the same reference numerals, and detailed descriptions thereof will be omitted.

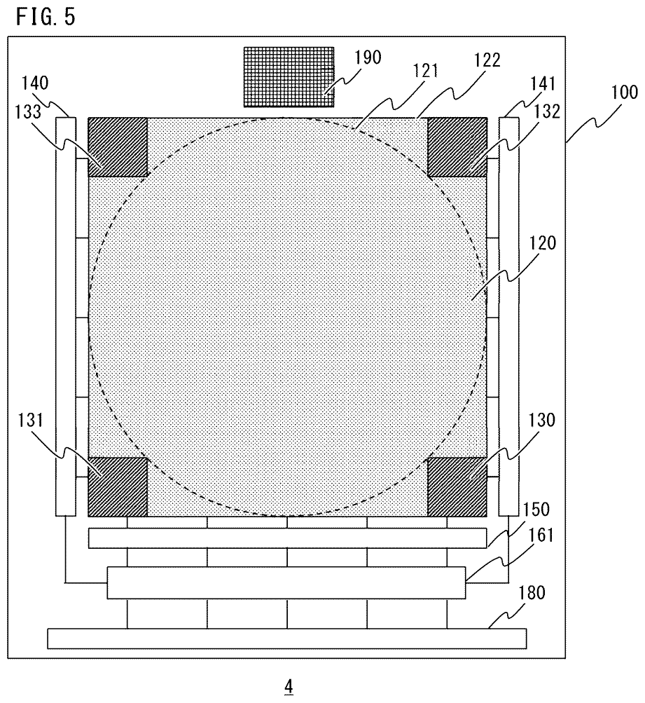

FIG. 5 is a schematic plan view of a display device 4 according to the fourth embodiment. In the display device 4 according to this embodiment, the display area 120, the infrared light-emitting areas 130 to 133, the display scanning circuits 140, 141, the demultiplexer 150, the DDIC 161, the pad 180, and a sensor 190 are disposed on the substrate 100.

In FIG. 5, the sensor 190 is disposed on the side above the display area 120 and outside the quadrangle 122. The sensor 190 includes an infrared receiving area including an infrared light-receiving element such as a photodiode, a sensor scanning circuit, and a received optical signal processing circuit. In this embodiment, infrared light is emitted from the infrared light-emitting areas 130 to 133 toward an eyeball of the user, and the light reflected from the eyeball is received by the photodiode in the sensor 190. Signals resultant of light received by the sensor 190 are sequentially selected and read by the sensor scanning circuit, and output to the light-receiving signal processing circuit. The light-receiving signal processing circuit includes elements such as a CDS circuit and an ADC. The sensor scanning circuit and the light-receiving signal processing circuit may be driven by receiving control signals from the DDIC 161, or may be connected to the pad 180 and driven by receiving control signals from the outside of the substrate 100.

The signal digitized by the light-receiving signal processing circuit is processed by an external line-of-sight detection circuit via the pad 180, and the line of sight vector of the user is calculated. It is also possible to dispose the pad connected to such an external component on the side above the sensor 190. It is also possible for the line-of-sight detection circuit to be mounted on the substrate 100.

As described above, with the display device 4 according to this embodiment, because the sensor 190 is disposed on the substrate 100, it is possible to achieve a line-of-sight detection display device including the sensor 190. In FIG. 5, the display scanning circuits 140, 141, and the demultiplexer 150 are provided on the left side, the right side, and the side below the display area 120, respectively. Therefore, by disposing the sensor 190 on the side above the display area 120, the sensor 190 can be positioned near the center of the display area 120. In this embodiment, by further reducing the reflection angle of the light reflecting from the user's cornea, the detection probability is improved, so that the accuracy of line-of-sight detection can be improved, compared with that in the first to third embodiments.

Furthermore, in the embodiments described above, each of the infrared light-emitting areas may have a configuration only including an infrared light-emitting element.

The display device according to any one of embodiments of the present disclosure may include an organic light-emitting element as an example of the light-emitting element.

[Structure of Organic Light-Emitting Element] An organic light-emitting element used for a display device of the present embodiments as described above will be explained next. The organic light-emitting element is provided by forming an insulating layer, a first electrode, an organic compound layer and a second electrode, on a substrate. A protective layer, a color filter, a microlens and so forth may be provided on a cathode. In a case where a color filter is provided, a planarization layer may be provided between the color filter and the protective layer. The planarization layer can be for instance made up of an acrylic resin. The same is true in a case where the planarization layer is provided between the color filter and the microlens.

[Substrate] At least one material selected from quartz, glass, silicon, resins and metals can be used as the material for the substrate that makes up the organic light-emitting element. Switching elements such as transistors and wiring may be provided on the substrate, and an insulating layer may be provided on the foregoing. Any material can be used as the insulating layer so long as a contact hole can be formed between the insulating layer and the first electrode, and insulation from unconnected wiring can be ensured, so that wiring can be formed between the first electrode and the insulating layer. For instance a resin such as a polyimide, or silicon oxide or silicon nitride can be used herein.

[Electrodes] A pair of electrodes can be used as the electrodes of the organic light-emitting element. The pair of electrodes may be an anode and a cathode. In a case where an electric field is applied in the direction in which the organic light-emitting element emits light, the electrode of higher potential is the anode, and the other electrode is the cathode. Stated otherwise, the electrode that supplies holes to the light-emitting layer is the anode, and the electrode that supplies electrons is the cathode.

A material having a work function as large as possible is preferable herein as a constituent material of the anode. For instance single metals such as gold, platinum, silver, copper, nickel, palladium, cobalt, selenium, vanadium or tungsten, and mixtures containing the foregoing metals, can be used in the anode. Alternatively, alloys obtained by combining these single metals, or metal oxides such as tin oxide, zinc oxide, indium oxide, indium tin oxide (ITO) or indium zinc oxide, may be used in the anode. Conductive polymers such as polyaniline, polypyrrole and polythiophene can also be used in the anode.

Any of the foregoing electrode materials may be used singly; alternatively, two or more materials may be used concomitantly. The anode may be made up of a single layer, or may be made up of a plurality of layers. In a case where an electrode of the organic light-emitting element is configured in the form of a reflective electrode, the electrode material can be for instance chromium, aluminum, silver, titanium, tungsten, molybdenum, or alloys or layered bodies of the foregoing. The above materials can also function as a reflective film not having a role as an electrode. In a case where an electrode of the organic light-emitting element is configured in the form of a transparent electrode, for instance an oxide transparent conductive layer of for instance indium tin oxide (ITO) or indium zinc oxide can be used, although not particularly limited thereto, as the electrode material. The electrodes may be formed by photolithography.

A material having a small work function may be a constituent material of the cathode. For instance alkali metals such as lithium, alkaline earth metals such as calcium, single metals such as aluminum, titanium, manganese, silver, lead or chromium, and mixtures of the foregoing, may be used herein. Alternatively, alloys obtained by combining these single metals can also be used. For instance magnesium-silver, aluminum-lithium, aluminum-magnesium, silver-copper or zinc-silver can be used. Metal oxides such as indium tin oxide (ITO) can also be used. These electrode materials may be used singly as one type, or two or more types can be used concomitantly. Also, the cathode may have a single-layer structure or a multilayer structure. Silver is preferably used among the foregoing, and more preferably a silver alloy, in order to reduce silver aggregation. Any alloy ratio can be adopted, so long as silver aggregation can be reduced. A ratio silver:other metal may be for instance 1:1, or 3:1.

Although not particularly limited thereto, the cathode may be a top emission element that utilizes an oxide conductive layer of ITO or the like, or may be a bottom emission element that utilizes a reflective electrode of aluminum (Al) or the like. The method for forming the cathode is not particularly limited, but more preferably for instance a DC or AC sputtering method is resorted to, since in that case film coverage is good and resistance can be readily lowered.

[Pixel Separation Layer] The pixel separation layer of the organic light-emitting element is formed out of a silicon nitride (SiN) film, a silicon oxynitride (SiON) film, or a silicon oxide (SiO) film, in turn having been formed by chemical vapor deposition (CVD). In order to increase the in-plane resistance of the organic compound layer, preferably the thickness of the organic compound layer that is formed, particularly a hole transport layer, is set to be small at the side walls of the pixel separation layer. Specifically, the side walls can be formed to be thin by increasing vignetting at the time of deposition, through an increase of the taper angle of the side walls of the pixel separation layer and/or an increase of the thickness of the pixel separation layer.

On the other hand, it is preferable to adjust the side wall taper angle of the pixel separation layer and the thickness of the pixel separation layer so that no voids are formed in the protective layer that is formed on the pixel separation layer. The occurrence of defects in the protective layer can be reduced by virtue of the fact that no voids are formed in the protective layer. Since the occurrence of defects in the protective layer is thus reduced, it becomes possible to reduce loss of reliability for instance in terms of the occurrence of dark spots or defective conduction in the second electrode.

The present embodiment allows effectively suppressing leakage of charge to adjacent pixels even when the taper angle of the side walls of the pixel separation layer is not sharp. Studies by the inventors of the present application have revealed that leakage of charge to adjacent pixels can be sufficiently reduced if the taper angle lies in the range at least 60 degrees and not more than 90 degrees. The thickness of the pixel separation layer is preferably at least 10 nm and not more than 150 nm. A similar effect can be achieved also in a configuration having only a pixel electrode lacking a pixel separation layer. In this case, however, it is preferable to set the film thickness of the pixel electrode to be half or less the thickness the organic layer, or to impart forward taper at the ends of the pixel electrode, at a taper angle smaller than 60 degrees, since short circuits of the organic light-emitting element can be reduced thereby.

[Organic Compound Layer] The organic compound layer of the organic light-emitting element may be formed out of a single layer or multiple layers. In a case where the organic compound layer has multiple layers, these may be referred to as a hole injection layer, a hole transport layer, an electron blocking layer, a light-emitting layer, a hole blocking layer, an electron transport layer or an electron injection layer, depending on the function of the layer. The organic compound layer is mainly made up of organic compounds, but may contain inorganic atoms and inorganic compounds. For instance the organic compound layer may have copper, lithium, magnesium, aluminum, iridium, platinum, molybdenum or zinc. The organic compound layer may be disposed between the first electrode and the second electrode, and may be disposed in contact with the first electrode and the second electrode.

In the case of multiple light-emitting layers, the first and second light-emitting layers may have a charge generating portion between the first and second light-emitting layers. The charge generating portion may have an organic compound with a lowest unoccupied molecular orbital energy (LUMO) of-5.0 eV or less. The same is true in the case of providing a charge generating section between the second and third light-emitting layers.

[Protective Layer] A protective layer may be provided on the second electrode. For instance, intrusion of water or the like into the organic compound layer can be reduced, and the occurrence of display defects also reduced, by bonding a glass provided with a moisture absorbent onto the second electrode. As another embodiment, a passivation film of for instance silicon nitride may be provided on the cathode, to reduce intrusion of water or the like into the organic compound layer. For instance, formation of the cathode may be followed by conveyance to another chamber, without breaking vacuum, whereupon a protective layer may be formed through formation of a silicon nitride film having a thickness of 2 μm by CVD. The protective layer may be provided by atomic deposition (ALD), after film formation by CVD. The material of the film formed by ALD is not limited, but may be for instance silicon nitride, silicon oxide or aluminum oxide. Silicon nitride may be further formed, by CVD, on the film having been formed by ALD. The film formed by ALD may be thinner than the film formed by CVD. Specifically, the thickness of the film formed by ALD may be 50% or less, or 10% or less.

[Color Filter] A color filter may be provided on the protective layer of the organic light-emitting element of the present embodiment. For instance a color filter having factored therein the size of the organic light-emitting element may be provided on another substrate, followed by affixing to a substrate having the organic light-emitting element provided thereon; alternatively, a color filter may be patterned by photolithography on the protective layer illustrated above. The color filter may be made up of a polymer.

[Planarization Layer] The organic light-emitting element may have a planarization layer between the color filter and the protective layer. The planarization layer is provided for the purpose of reducing underlying layer unevenness. The planarization layer may be referred to as a resin layer in a case where the purpose of the planarization layer is not limited. The planarization layer may be made up of an organic compound, which may be a low-molecular or high-molecular compound, preferably a high-molecular compound. The planarization layer may be provided above and below the color filter, and the constituent materials of the respective planarization layers may be identical or dissimilar. Concrete examples include polyvinylcarbazole resins, polycarbonate resins, polyester resins, ABS resins, acrylic resins, polyimide resins, phenolic resins, epoxy resins, silicone resins and urea resins.

[Microlens] The display device may have an optical member such as a microlens, on the light exit side. The microlens may be made up of for instance an acrylic resin or an epoxy resin. The purpose of the microlens may be to increase the amount of light extracted from the display device, and to control the direction of the extracted light. The microlens may have a hemispherical shape. In a case where the microlens has a hemispherical shape, then from among tangent lines that are in contact with the hemisphere there is a tangent line that is parallel to the insulating layer, such that the point of contact between that tangent line and the hemisphere is the apex of the microlens. The apex of the microlens can be established similarly in any cross section. That is, among tangent lines that are in contact with a semicircle of the microlens in a sectional view, there is a tangent line that is parallel to the insulating layer, such that the point of contact between that tangent line and the semicircle is the apex of the microlens.

A midpoint of the microlens can also be defined. Given a hypothetical line segment from the end point of an arc shape to the end point of another arc shape, in a cross section of the microlens, the midpoint of that line segment can be referred to as the midpoint of the microlens. The cross section for discriminating the apex and the midpoint may be a cross section that is perpendicular to the insulating layer.

The microlens has a first surface with a bulge and a second surface on the reverse side from that of the first surface. Preferably, the second surface is disposed closer to a functional layer than the first surface. In adopting such a configuration, the microlens must be formed on the display device. In a case where the functional layer is an organic layer, it is preferable to avoid high-temperature processes in the manufacturing process. If a configuration is adopted in which the second surface is disposed closer to the functional layer than the first surface, the glass transition temperatures of all the organic compounds that make up the organic layer are preferably 100° C. or higher, and more preferably 130° C. or higher.

[Counter Substrate] The organic light-emitting element of the present embodiment may have a counter substrate on the planarization layer. The counter substrate is so called because it is provided at a position corresponding to the above-described substrate. The constituent material of the counter substrate may be the same as that of the substrate described above. The counter substrate can be used as the second substrate in a case where the substrate described above is used as the first substrate.

[Organic Layer] Each organic compound layer (hole injection layer, hole transport layer, electron blocking layer, light-emitting layer, hole blocking layer, electron transport layer, electron injection layer, and so forth) that makes up the organic light-emitting element used for a display device of the present embodiments is formed in accordance with one of the methods illustrated below.

A dry process, such as vacuum deposition, ionization deposition, sputtering, plasma or the like, can be used for the organic compound layers that make up the organic light-emitting element of the present embodiment. A wet process in which a layer is formed through dissolution in an appropriate solvent, relying on a known coating method (e.g., spin coating, dipping, casting, LB film deposition to inkjet) can resorted to instead of a dry process.

When a layer is formed, for example, by vacuum deposition or by solution coating, crystallization or the like is less likely to occur; this translates into superior stability over time. In a case where a film is formed in accordance with a coating method, the film can be formed by being combined with an appropriate binder resin.

Examples of binder resins include, although they are not limited to, polyvinylcarbazole resins, polycarbonate resins, polyester resins, ABS resins, acrylic resins, polyimide resins, phenolic resins, epoxy resins, silicone resins, and urea resins.

These binder resins may be used singly as one type, in the form of homopolymers or copolymers; also, two or more types of binder resin may be used in the form of mixtures. Additives such as known plasticizers, antioxidants, and ultraviolet absorbers may be further used concomitantly, as needed.

[Pixel Driving Circuit] Pixel driving circuits may be connected to respective organic light-emitting elements. The pixel driving circuits may be of active matrix type, and may control independently emission of light by the first organic light-emitting element and the second organic light-emitting element. Active matrix circuits may be voltage-programmed or current-programmed. A display device has a pixel circuit for each pixel. Each pixel circuit may have an organic light-emitting element, a transistor that controls the emission luminance of the organic light-emitting element, a transistor that controls emission timing, a capacitor which holds the gate voltage of the transistor that controls emission luminance, and a transistor for connection to GND bypassing the light-emitting element.

The organic light-emitting element has a display area and a peripheral area disposed around the display area. The display area has pixel driving circuits, and the peripheral area has a display control circuit. The mobility of the transistors that make up the pixel driving circuits may be lower than the mobility of the transistors that make up the display control circuit. The slope of the current-voltage characteristic of the transistors that make up the pixel driving circuits may be gentler than the slope of the current-voltage characteristic of the transistors that make up the display control circuit. The slope of the current-voltage characteristics can be measured on the basis of a so-called Vg-Ig characteristic. The transistors that make up the pixel driving circuits are connected to light-emitting elements, such as the first organic light-emitting element.

[Pixels] The organic light-emitting element has a plurality of pixels. The pixels have sub-pixels that emit mutually different colors. The sub-pixels may have, for example, respective RGB emission colors.

The pixels emit light in a pixel opening region. This region is the same as the first region. The aperture diameter of the pixel openings may be 15 μm or smaller, and may be 5 μm or larger. More specifically, the aperture diameter of the pixel openings may be, for example, 11 μm, or 9.5 μm, or 7.4 μm, or 6.4 μm. The spacing between sub-pixels may be 10 μm or smaller, specifically 8 μm, or 7.4 μm, or 6.4 μm, for example.

The pixels can have any known arrangement in a plan view. For example, the pixel layout may be a stripe arrangement, a delta arrangement, a Pen tile arrangement, or a Bayer arrangement. The shape of the sub-pixels in a plan view may be any known shape. For example, the sub-pixel shape may be, for example, quadrangular, such as rectangular or rhomboidal, or may be hexagonal. Needless to say, the shape of the sub-pixels is not an exact shape, and a shape close to that of rectangle falls under a rectangular shape. Sub-pixel shapes and pixel arrays can be combined with each other.

[Use of the Display Device According to One of the Present Embodiments] The display device according to the first to third embodiments can be used as a constituent member of a variety of equipment and devices. Other uses of the display device include light-emitting devices having color filters, in white light sources.

The display device may be an image information processing device having an image input unit for input of image information, for example from an area CCD, a linear CCD, or a memory card, and an information processing unit for processing inputted information, such that an inputted image is displayed on a display unit. The display unit may include the display device according to any one of the first to third embodiments.

A display unit of an imaging device or of an inkjet printer may have the display device according to any one of the first to third embodiments. The display unit may have a touch panel function. The driving scheme of this touch panel function may be an infrared scheme, a capacitive scheme, a resistive film scheme, or an electromagnetic induction scheme, and is not particularly limited. The display device may also be used in a display unit of a multi-function printer.

Next, examples of the display device according to one of the present embodiments will be described with reference to the drawings.

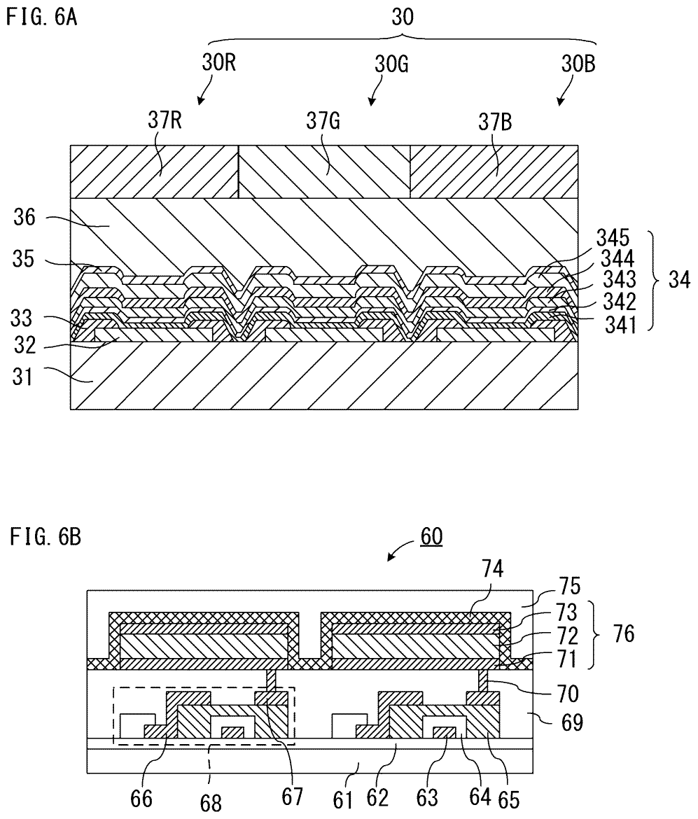

FIG. 6A and FIG. 6B are cross-sectional schematic diagrams illustrating examples of a display device having organic light-emitting elements and transistors connected to respective organic light-emitting elements. The transistors are an example of active elements. The transistors may be thin-film transistors (TFTs).

FIG. 6A is an example of a pixel, which is a constituent element of a display device having the organic light-emitting element according to the present embodiment. The pixel has sub-pixels 30. The sub-pixels are divided into 30R, 30G and 30B, depending on the respective emission light of the sub-pixel. The emission color may be made different on the basis of the wavelength emitted from the light-emitting layer; alternatively, the light emitted from each sub-pixel may be selectively transmitted or color-converted for instance by a respective color filter. Each sub-pixel has a reflective electrode 32 as a first electrode on an interlayer insulating layer 31, and an insulating layer 33 that covers the edge of the reflective electrode 32. Each sub-pixel has an organic compound layer 34 that covers the reflective electrode 32 and the insulating layer 33, a transparent electrode 35 as a second electrode, a protective layer 36, and a respective color filter 37R, 37G or 37B.

The interlayer insulating layer 31 may have transistors and capacitive elements disposed thereunder or in the interior. The transistors and the first electrode may be electrically connected for instance by way of contact holes (not shown).

The insulating layer 33 is also referred to as a bank or as pixel separation film. The insulating layer 33 is disposed covering the edge of the first electrode while surrounding the first electrode. Portions where the insulating layer is not disposed are in contact with the organic compound layer 34, yielding emission regions. The organic compound layer 34 has a hole injection layer 341, a hole transport layer 342, a first light-emitting layer 343, a second light-emitting layer 344 and an electron transport layer 345.

The transparent electrode 35, as the second electrode, may be a transparent electrode, a reflective electrode, or a semi-transparent electrode. The protective layer 36 reduces permeation of moisture into the organic compound layer. The protective layer 36 is illustrated herein in the form of one layer, but may be multiple layers. Each protective layer 36 may have an inorganic compound layer or an organic compound layer. The color filters are divided into a color filter 37R, a color filter 37G and a color filter 37B, according to the color thereof. The color filters may be formed on a planarization film, not shown. A resin protective layer, not shown, may be provided on the color filters. The color filters may be formed on the protective layer 36. Alternatively, the color filters may be affixed after having been provided on a counter substrate such as a glass substrate.

FIG. 6B illustrates a display device 60 having the organic light-emitting element of the present embodiment. The display device 60 has organic light-emitting elements 76 and TFTs 68 as an example of a transistor. The display device 60 is provided with a substrate 61 made up of glass, silicon or the like, and an insulating layer 62 at the top of the substrate 61. Respective active elements such as TFTs 68 are disposed on the insulating layer 62, such that a gate electrode 63, a gate insulating film 64 and a semiconductor layer 65 of each active element are disposed therein. Each TFT 68 is also made up of the semiconductor layer 65, a drain electrode 66 and a source electrode 67. An insulating film 69 is provided on the TFTs 68. An anode 71 and a source electrode 67 that make up a respective organic light-emitting element 76 are connected through a contact hole 70 provided in the insulating film 69.

The method for electrically connecting the electrodes (anode and cathode) included in each organic light-emitting element 76 and the electrodes (source electrode and drain electrode) included in the respective TFT 68 is not limited to the implementation illustrated in FIG. 6B. Specifically, it suffices that either one from among the anode and the cathode be electrically connected to either a TFT source electrode or a TFT drain electrode. The acronym TFT signifies thin-film transistor.

In the display device 60 of FIG. 6B, the organic compound layer is illustrated as one layer, but the organic compound layer 72 may be a plurality of layers. A first protective layer 74 and a second protective layer 75 for reducing deterioration of the organic light-emitting element are provided on the cathode 73.

Although transistors are used as switching elements in the display device 60 of FIG. 6B, other switching elements may be used instead. The transistors used in the display device 60 of FIG. 6B are not limited to transistors that utilize a single-crystal silicon wafer, and may be thin-film transistors having an active layer on an insulating surface of a substrate. Examples of active layers include single-crystal silicon, non-single-crystal silicon such an amorphous silicon or microcrystalline silicon, as well as non-single-crystal oxide semiconductors such as indium zinc oxide or indium gallium zinc oxide. Thin-film transistors are also referred to as TFT elements.

The transistors included in the display device 60 of FIG. 6B may be formed in a substrate such as a Si substrate. The wording “formed in a substrate” signifies that transistors are produced by processing the substrate itself, for instance a Si substrate. That is, the feature of having transistors in the substrate may signify that the substrate and the transistors are integrally formed with each other.

The emission luminance of the organic light-emitting element according to the present embodiment is controlled by a TFT, which is an example of a switching element; an image can be thus displayed according to respective values of emission luminance, by providing a plurality of organic light-emitting elements within a plane. The switching element according to the present embodiment is not limited to a TFT, and may be a transistor made up of low-temperature polysilicon, or an active matrix driver formed on a substrate such as a Si substrate. The wording “on the substrate” can also signify herein “in the substrate”. The size of the display unit governs the choice of whether the transistors are to be provided in the substrate, or whether TFTs are to be used; if for instance the size of the display unit is about 0.5 inches, it is preferable to provide the organic light-emitting elements on a Si substrate.

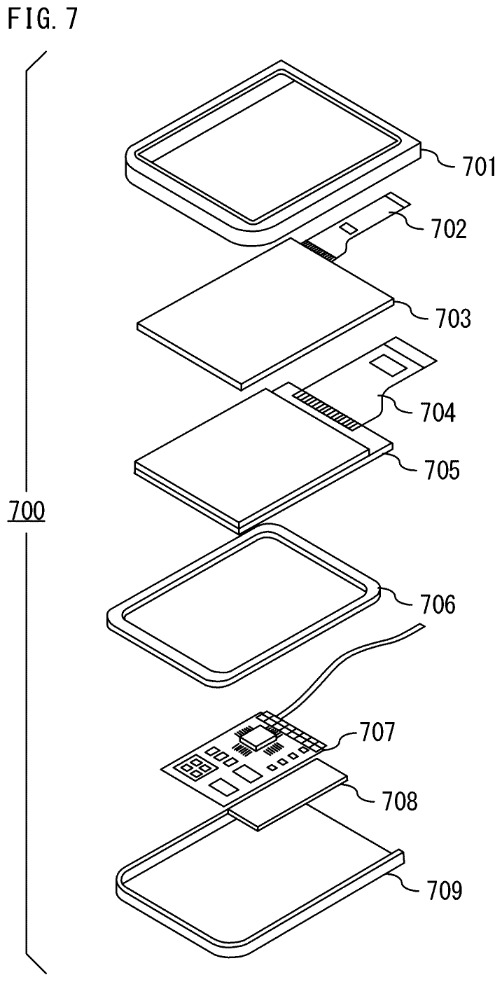

FIG. 7 illustrates a schematic diagram depicting an example of a display device according to any one of the embodiments as described above. A display device 700 may have a touch panel 703, a display panel 705, a frame 706, a circuit board 707, and a battery 708, between an upper cover 701 and a lower cover 709. The touch panel 703 and the display panel 705 are connected to flexible printed circuits FPCs 702, 704. Transistors are printed on the circuit board 707. The battery 708 may be omitted if the display device is not a portable device; even if the display device is a portable device, the battery 708 may be provided at a different position.

The display device 700 may have red, green and blue color filters. The color filters may be disposed in a delta arrangement of the above red, green and blue.

The display device 700 may be used as a display unit of a mobile terminal. In that case the display device 700 may have both a display function and an operation function. Mobile terminals include mobile phones such as smartphones, tablets and head-mounted displays.

The display device 700 may be used in a display unit of an imaging device that has an optical unit having a plurality of lenses and that has an imaging element that receives light having passed through the optical unit. The imaging device may have a display unit that displays information acquired by the imaging element. The display unit may be a display unit exposed outside the imaging device, or the display unit may be a display unit disposed within a viewfinder. The imaging device may be a digital camera or a digital video camera.

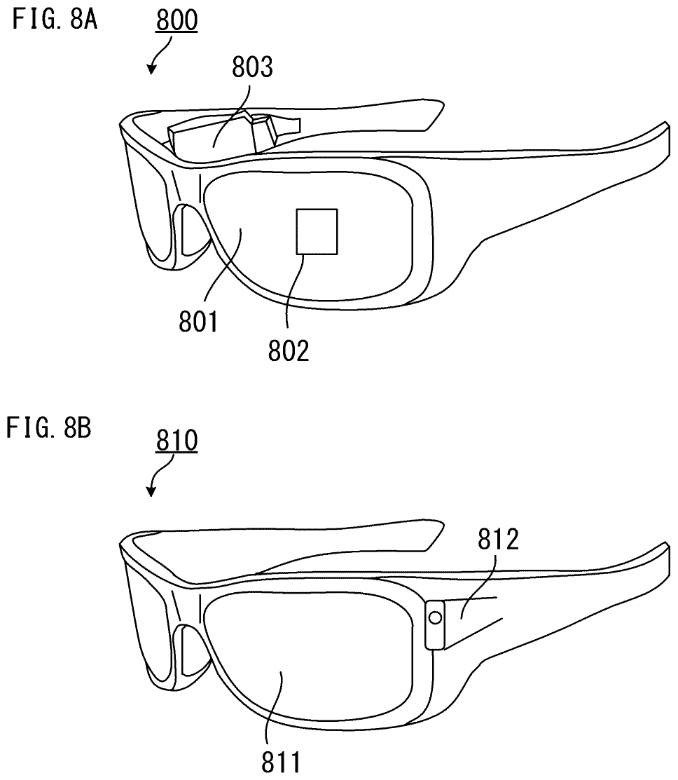

Next, application examples of the display devices according to the first to third embodiments are described referring to FIG. 8A and FIG. 8B. Display devices may be applied to systems that may be worn as wearable devices, such as smart glasses, HMDs, and smart contacts, for example. The imaging device and display device used in such application examples may be an imaging device capable of photoelectrically converting visible light and a display device capable of emitting visible light.

FIG. 8A illustrates spectacles 800 (smart glasses) according to an application example of the display device of the present disclosure. An imaging device 802 such as a CMOS sensor or a SPAD is provided on the front surface side of a lens 801 of the spectacles 800. A display device according to any one of the above embodiments is provided on the back surface side of the lens 801.

The spectacles 800 further have a control device 803. The control device 803 functions as a power supply that supplies power to the imaging device 802 and to the display device. The control device 803 controls the operations of the imaging device 802 and of the display device. The lens 801 has formed therein an optical system for condensing light onto the imaging device 802.

FIG. 8B illustrates spectacles 810 (smart glasses) according to another application example of the display device of the present disclosure. The spectacles 810 have a control device 812. The control device 812 has mounted therein an imaging device corresponding to the imaging device 802 and a display device. In a lens 811 there is formed an optical system for projecting the light emitted by the display device in the control device 812, such that an image is projected onto the lens 811. The control device 812 functions as a power supply that supplies power to the imaging device and to the display device, and the control device 812 controls the operations of the imaging device and of the display device. The control device 812 may have a line-of-sight detection unit that detects the line of sight of the wearer. Infrared rays may be used herein for line-of-sight detection. An infrared light-emitting unit emits infrared light towards one eyeball of a user who is gazing at a display image. The infrared light emitted is reflected by the eyeball and is detected by an imaging unit having a light-receiving element, whereby a captured image of the eyeball is obtained as a result. Impairment of the appearance of the image is reduced herein by having a reducing means for reducing light from the infrared light-emitting unit to the display unit, in a plan view.

The line of sight of the user with respect to the display image is detected on the basis of the captured image of the eyeball obtained through infrared light capture. Any known method can be adopted for line-of-sight detection using the captured image of the eyeball. As an example, a line-of-sight detection method can be resorted to that utilizes Purkinje images obtained through reflection of irradiation light on the cornea.

More specifically, line-of-sight detection processing based on a pupillary-corneal reflection method is carried out herein. The line of sight of the user is detected by calculating a line-of-sight vector that represents the orientation (rotation angle) of the eyeball, on the basis of a Purkinje image and a pupil image included in the captured image of the eyeball, in accordance with a pupillary-corneal reflection method.

The spectacles 810 may have an imaging device having a light-receiving element, and may control the display image of the display device on the basis of line-of-sight information about the user, from the imaging device.

Specifically, a first display area gazed at by the user and a second display area, other than the first display area, are determined in the display device on the basis of line-of-sight information. The first display area and the second display area may be determined by the control device of the spectacles 810; also, the display device may receive visual field areas determined by an external control device. In a display area of the display device, the display resolution in the first display area may be controlled to be higher than the display resolution in the second display area. That is, the resolution in the second display area may set to be lower than that of the first display area.

The display area may have a first display area and a second display area different from the first display area, such that the display device selects the area of higher priority, from among the first display area and the second display area, on the basis of the line-of-sight information. The first display area and the second display area may be determined by the control device of the display device; also, the display device may receive display areas determined by an external control device. The display device may control the resolution in a high-priority area so as to be higher than the resolution in areas other than high-priority areas. That is, the display device may lower the resolution in areas of relatively low priority.

Herein AI (Artificial Intelligence) may be used to determine the first display area and high-priority areas. The AI may be a model constructed to estimate, from an image of the eyeball, a line-of-sight angle and the distance to an object lying ahead in the line of sight, using training data in the form of the image of the eyeball and the direction towards which the eyeball in the image was actually gazing at. An AI program may be provided in the display device, in the imaging device, or in an external device. In a case where an external device has the AI program, the AI program is transmitted to the display device via communication from the external device.

In a case where the display device performs display control on the basis of on visual recognition detection, the display device can be preferably used in smart glasses further having an imaging device that captures images of the exterior. The smart glasses can display captured external information in real time.

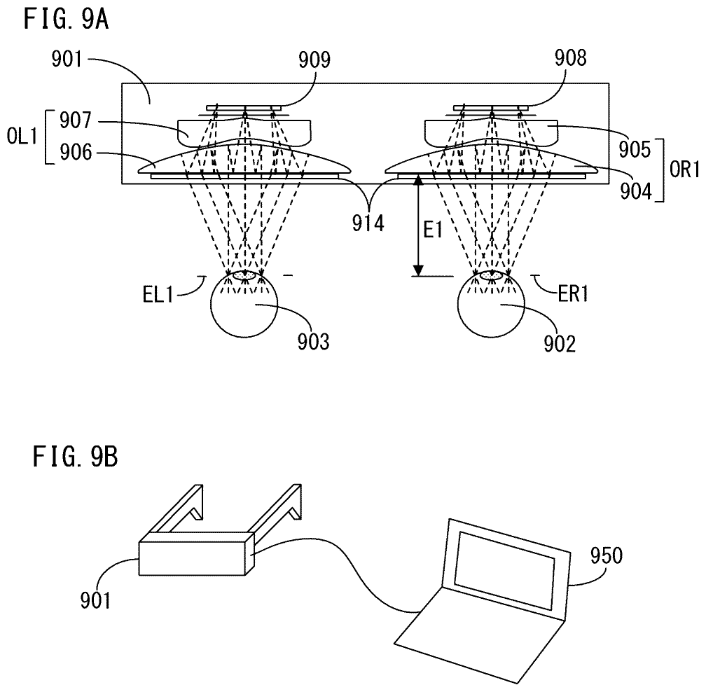

FIG. 9A is a diagram illustrating a configuration of an HMD (head mounted display) 901 as an image observation device according to the present embodiment. The HMD 901 is worn on the head of the viewer. Reference numeral 902 denotes the right eye of the observer, and reference numeral 903 denotes the left eye of the observer. The display lenses 904 and 905 constitute the eyepiece optical system OR1 for the right eye, and the display lenses 906 and 907 constitute the eyepiece optical system OL1 for the left eye. Each eyepiece optical system is a coaxial optical system including a plurality of (two) display lenses. The right eye 902 of the observer is disposed on the exit pupil ER1 of the right eyepiece optical system OR1, and the left eye 903 of the observer is disposed on the exit pupil EL1 of the left eyepiece optical system OL1.

Reference numerals 908 and 909 denote a display device for the right eye and a display device for the left eye, respectively. These display devices may be the display devices according to any one of the first to fourth embodiments. FIG. 9B is a diagram illustrating an appearance of the HMD 901 and a personal computer 950 connected thereto. Each display device displays a display image (original image) corresponding to an image signal output from the personal computer 950. In the present embodiment, the connection is achieved in a wired manner, but the connection may be achieved in a wireless manner. The HMD 901 may be a device that incorporates an image processing apparatus and operates in a stand-alone mode.

The eyepiece optical systems OR1 and OL1 guide the light from the display devices 908 and 909 to the exit pupils ER1 and EL1, respectively, thereby projecting the enlarged virtual image of the display image to the right eye 902 and the left eye 903 of the viewer. Accordingly, the observer can observe (virtual images of) the display images displayed on the display devices 908 and 909 through the eyepiece optical systems OR1 and OL1.

Although not shown, the HMD 901 may include a controller. The control device functions as a power source for supplying electric power to the display devices 908 and 909, and controls the operation of the display devices 908 and 909.

The control device may include a line-of-sight detection unit that detects a line of sight of the wearer. The gaze may be detected using infrared light. The infrared light emitting unit emits infrared light to the eyeball of the user who is gazing at the display image. A captured image of the eyeball is obtained by detecting reflected light of the emitted infrared light from the eyeball by an imaging unit having a light receiving element. The reduction unit configured to reduce light from the infrared light emitting unit to the display unit in a plan view reduces degradation in image quality.

The gaze of the user with respect to the display image is detected from the captured image of the eyeball obtained by capturing the infrared light. Any known technique may be applied to the gaze detection using the captured image of the eyeball. As an example, a gaze detection method based on a Purkinje image due to reflection of irradiation light on the cornea can be used.

More specifically, the line-of-sight detection process based on the pupillary corneal reflection method is performed. The gaze of the user is detected by calculating a gaze vector representing the orientation (rotation angle) of the eyeball based on the image of the pupil included in the captured image of the eyeball and the Purkinje image using the pupil corneal reflex method.

Specifically, the display devices 908 and 909 determine a first display area to be gazed by the user and a second display area other than the first display area based on the line-of-sight information. The first display area and the second display area may be determined by the control device or may be received by an external control device. In the display regions of the display devices 908 and 909, the display resolution of the first display area may be controlled to be higher than the display resolution of the second display area. That is, the resolution of the second display area may be lower than that of the first display area.

The display region includes a first display area and a second display area different from the first display area, and a region with a higher priority is determined from the first display area and the second display area based on the line-of-sight information. The first display area and the second display area may be determined by a control device of the display device or may be received by an external control device. The resolution of the high priority region may be controlled to be higher than the resolution of the region other than the high priority region. That is, the resolution of the region having a relatively low priority may be lowered.

Note that AI may be used to determine the first display area or the region with high priority. AI may be a model configured to estimate the angle of the line of sight and the distance to the target object ahead of the line of sight from the image of the eyeball using the image of the eyeball and the direction in which the eyeball of the image is actually viewed as teacher data. The AI program may be included in the display device, the imaging device, or the external device. In a case where the external device has the information, the information is transmitted to the display device via communication.

According to the present disclosure, it is possible to improve the detection accuracy of the line of sight of a user, in a display device having a display area and an infrared light-emitting area.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-164109, filed on Sep. 20, 2024 and No. 2025-069279, filed on Apr. 21, 2025, which are hereby incorporated by reference herein in their entirety.

What is claimed is:

1. A display device comprising:
a display area provided on a substrate and including a visible-light-emitting element; and
a first infrared light-emitting area provided on the substrate and including an infrared light-emitting element,
wherein in a plan view of the substrate, the first infrared light-emitting area circumscribes the display area and is positioned between the display area and a polygon containing the display area.

2. The display device according to claim 1, further comprising a second infrared light-emitting area that includes an infrared light-emitting element and that is positioned between the display area and the polygon and but at a position different from the first infrared light-emitting area.

3. The display device according to claim 2, wherein the first infrared light-emitting area and the second infrared light-emitting area are positioned at mutually different facing corners of the polygon, respectively, with the display area interposed between the first infrared light-emitting area and the second infrared light-emitting area.

4. The display device according to claim 1, further comprising a third infrared light-emitting area including an infrared light-emitting element and disposed outside the polygon, in a plan view of the substrate.

5. The display device according to claim 1, wherein a scanning circuit of the display area is disposed along a first side of the polygon outside the polygon, in a plan view of the substrate.

6. The display device according to claim 5, wherein in a plan view of the substrate, a source driver of the display area is disposed along a second side that is different from the first side of the polygon, outside the polygon.

7. The display device according to claim 1, further comprising an infrared light-receiving element disposed outside the polygon, in a plan view of the substrate.

8. The display device according to claim 2, wherein each of the first infrared light-emitting area and the second infrared light-emitting area includes only the infrared light-emitting element.

9. The display device according to claim 4, wherein the third infrared light-emitting area includes only the infrared light-emitting element.

10. The display device according to claim 1, further comprising an optical system through which light emitted from the display area is passed, wherein
the display area has an octagonal shape in a plan view of the substrate, and the optical system has a circular shape inscribed in the octagonal shape in a plan view.

11. A device comprising a plurality of pixels, wherein
at least one of the plurality of pixels includes:
the display device according to claim 1; and
a transistor connected to the infrared light-emitting element.

12. An imaging device comprising:
an optical unit having a plurality of lenses;
an imaging element that receives light having passed through the optical unit; and
a display unit that displays an image captured by the imaging element,
wherein the display unit includes the display device according to claim 1.
